(19) United States
(12) Patent Application Publication
(10) Pub. No.: US 2013/0127551 A1
(43) Pub. Date: May 23, 2013

(54) CRYSTAL REFERENCE OSCILLATOR FOR NAVIGATION APPLICATIONS

(71) Applicant: George Hedley Strorm Rokos, Essex (GB)

(72) Inventor: George Hedley Strorm Rokos, Essex (GB)

(73) Assignee: ADAPTALOG LIMITED, Essex (GB)

(21) Appl. No.: 13/814,237

(22) PCT Filed: Jul. 29, 2011
(86) PCT No.: PCT/IB11/53385

§ 371 Date: Feb. 4, 2013

(30) Foreign Application Priority Data
Aug. 5, 2010 (GB) GB1013191.0

(51) Int. Cl. H03L 7/00

(52) U.S. Cl. CPC H03L 7/00
USPC 331/66; 331/65

(57) ABSTRACT

A resonator-controlled oscillator arrangement comprises a resonator-controlled oscillator of which the operating frequency is adjustable and a control circuit for setting the operating frequency of the oscillator. The control circuit is operative to set the operating frequency in dependence upon prevailing ambient conditions. The control circuit has a control input for initiating a set-up procedure during which the operating frequency of the oscillator is set to a value remote from any resonance frequency of a coupled mode that would cause an activity dip.

### FIELD OF THE INVENTION

This invention relates to crystal reference oscillators for use in navigation applications.

### BACKGROUND OF THE INVENTION

Stable frequency references are required for applications such as satellite positioning systems and distress beacons. In both cases, the requirement is for a frequency that is known with moderate absolute accuracy (typically a few parts-per-million) and with short-term stability that allows signals to be sensed in the presence of noise.

The conditions under which the system will be required to sense the signal will vary according to the application. Typical consumer positioning systems are currently required to work under only moderate climatic conditions; critical applications need to operate when the signals are attenuated, by rain for example, and the requirements for future volume applications are also likely to become more demanding. This generates a requirement for synchronous integration of the incoming signal over relatively long times, and the use of a correspondingly stable frequency reference.

By way of example, present-day commercial systems may require detection of a 1500-MHz input signal and a maximum 0.2-second integration time, with timing stability adequate to provide sensitivity that is within 1-dB of theoretical limits. This corresponds to a frequency Allan difference (between the first and second halves of the detection period) of about 2-ppb, with the effect of uniform drift being slightly less severe. Allan deviation for such systems therefore needs to be about 1.2-ppb.

Longer integration times would require inversely smaller variations, such as drift and Allan variance in the order of 1E-11/sec and 1E-10 respectively. In addition, these longer detection periods become significant relative to the users' requirements for correct detection, which means that the occurrence of frequency jumps large enough to disturb the measurements (i.e. larger than about half the allowable Allan difference) may need to be extremely rare. These requirements are outside the capabilities of compact and low power frequency references currently available.

The frequency references used for navigation systems typically use AT or SC cut crystals. The intended vibrational mode of such crystals is a wave that propagates between the large surfaces of a crystal plate. This mode typically has a frequency-versus temperature characteristic that is approximately third order. Given such a simple characteristic, it would in principle be possible to tune in accordance with a fixed tuning law that maintains the frequency constant in spite of varying temperature.

Unfortunately, the large dimension of the plate along the surface means that there will be other vibrational modes (“plate modes”) at frequencies that are near to the operating frequency and to its overtones. As these other modes have different temperature coefficients from the intended mode, it is difficult to avoid interaction with the intended mode at all operating temperatures.

Such interaction has two effects. The best-known effect is distortion in the frequency-temperature characteristic of the oscillator, often associated with a reduction in oscillation amplitude, the reduction leading to the generally-used nomenclature of “activity dip”. As illustration, a third-order characteristic that is typical of an oscillator using an AT crystal with significant coupling to a single plate mode is shown in FIG. 1. An activity dip for this oscillator occurs in the region around 40° C., where there is a significant departure from the expected third-order frequency characteristic. It should be noted that the terminology “activity dip” is used also for similar effects of mode coupling in other resonator types, such as dielectric resonators.

Lesser known, but potentially even more troublesome for navigation and recovery-beacon applications, are rapid and non-systematic changes in output frequency in the neighbourhood of the activity dips. A significant source of such “frequency steps” is coupling to the environment via plate modes, because these modes extend throughout the crystal plate, and therefore interact with any mountings. As a result, any relaxation of package or mounting strain can modify the frequency of the plate modes which, naturally, modifies the output frequency of the oscillator.

It is thus desirable to find an operating regime where interaction between the intended operational mode and coupled modes is small. In principle this may be achieved by minimising the coupling coefficient to the unwanted mode and/or by arranging for the loss of the unwanted mode to be high (otherwise expressed as maintaining low Q), and/or by ensuring that coincidence of the resonant frequency of the unwanted mode and the oscillation frequency only occurs sufficiently far outside the operational temperature range.

To mitigate some of the problems described above, oven-stabilised crystal oscillators (more commonly called Oven Controlled Crystal Oscillators or OCXO) and Temperature compensated crystal oscillators (TCXO) have previously been proposed, see for example “Crystal Oscillator Design and Temperature Compensation” by Marvin E Frerking (Van Nostrand Reinhold, 1978). As regards OCXO solutions neither the dimensions nor the power requirements are compatible with ultra-portable equipments. The over-temperature resonator stability issues described above mean that at some temperatures even the best resonator designs fail to meet the system requirements described above, an issue that becomes more problematical as crystal sizes become smaller.

One potential solution for low-power systems is the use of multiple compensated oscillators. In the simplest case these might similarly compensate all oscillators and use the mean frequency of the outputs as the reference.

Advantageously, they may instead measure the correlations within the group, and discard output data from any oscillator whose frequency is temporarily inadequately correlated with the remainder of the group and reinstate once correlation becomes reliable (Proc. European Frequency and Tome Forum 2004, pp 570-575). Such an arrangement, however, requires a minimum of three oscillators operating quasi-continuously.

In U.S. Pat. No. 6,545,550, Frerking describes an oscillator arrangement that uses knowledge regarding the over-temperature behaviour multiple resonances to compensate for factors including but not necessarily restricted to instantaneous temperature. In particular, Frerking addresses effects related to mechanical strain that can be caused by relaxation of the electrodes and the mounting. In addition, he describes the possibility of using sufficient resonances that the frequency data of an individual resonance can be neglected at temperatures where its behaviour is previously calibrated to be sub-optimal. The arrangements described by Frerking are however quite specific, in that they require at least two oscillation frequencies to be compared against one another during use.

### SUMMARY OF THE INVENTION

With a view to mitigating the foregoing problems, the present invention provides in accordance with a first aspect a resonator-controlled oscillator arrangement, comprising a resonator-controlled oscillator of which the operating frequency is adjustable and a control circuit for setting the operating frequency of the oscillator, wherein the control circuit is operative to set the operating frequency in dependence upon prevailing ambient conditions, and wherein the control circuit has a control input for initiating a set-up procedure during which the operating condition of the oscillator is set to, or maintained at, a value remote from any resonance frequency of a coupled mode that would cause an activity dip.

According to a second aspect of the invention, there is provided a method of operating a resonator-controlled oscillator arrangement that comprises a resonator-controlled oscillator of which the operating frequency is adjustable and a control circuit for setting the operating frequency of the oscillator, the method being characterised by the steps of applying an initiation signal to an input of the control circuit prior to the commencement of a critical period during which the output frequency of the oscillator is to be maintained stable, selecting by the control circuit an operating frequency value that is remote from any resonance frequency of a coupled mode that would cause an activity dip at the prevailing ambient conditions, and setting or maintaining the operating frequency of the oscillator at the selected value for the duration of the critical period.

The different operational frequencies of the oscillator can correspond to different overtone frequencies of the resonator, or they can correspond to different modes of vibration or to anharmonic or inharmonic resonances. Alternatively, a single resonance mode can be tuned to provide different oscillation frequencies selected according to the operational temperature. Clearly, multiple oscillation frequencies can be accessed using a combination of these methods.

In an embodiment of the invention, the control circuit is further operative to produce an output signal indicative of the value to which the operating frequency of the oscillator has been set.

The tuning of the operating frequency of the oscillator remote from the resonance frequency of the activity dip may suitable be achieved by means of a switched capacitance or capacitances.

At least one of the switched capacitors may additionally serve as a temperature-compensating capacitor.

Advantageously, the control circuit comprises an environmental parameter measurement input and the set-up procedure uses the environmental data and a look-up table to determine the operating frequency of the oscillator.

The measured environmental parameter is commonly instantaneous temperature, this being the most critical, but other environmental parameters that affect the operating frequency of the oscillator may additionally be taken into account. These environmental parameters may be the instantaneous values, or they may take account of the recent history of the device.

In an embodiment of the invention, an oscillation signal from the resonator controlled oscillator is applied to an input to the control circuit, and the set-up procedure utilises parameters of the oscillation signal at a plurality of operating frequencies to determine the occurrence of an activity dip. The occurrence of an activity dip may be determined by the control circuit from the amplitude of the oscillation signal to the frequency adjustment setting to the frequency adjustment setting or, where the output amplitude is stabilised, by the response of the amplitude stabilisation signal for oscillators where the output amplitude is stabilised.

It is possible to stabilise the temperature of the oscillator during a measurement period, but as an alternative the control circuit may act to tune the oscillator in dependence upon a signal indicative of environmental conditions, such as to maintain the operating frequency at a constant value during a measurement period; a further alternative is to allow the frequency to vary and to provide data to the user that is indicative of the deviation of the operating frequency from its value under some known condition.

### BRIEF DESCRIPTION OF THE DRAWINGS

The invention will now be described further, by way of example, with reference to the accompanying drawings, in which:

FIG. 1, as earlier described, shows a typical frequency-temperature characteristic of a quartz AT crystal with an activity dip centred at 40° C.,

FIG. 2 shows how the temperature of the activity dip changes with the operating frequency of the oscillator,

FIG. 3 shows only the sections of the graphs in FIG. 2 that are relatively unaffected by any activity dip.

FIG. 4 is a block diagram of an arrangement of the invention that uses stored data and temperature measurement to determine the setting of the operating frequency,

FIG. 5 is a block diagram of an arrangement of the invention that measures oscillation amplitude over the tuning range to provide the data that determines the setting for the operating frequency, and

FIG. 6 is a block diagram of an arrangement of the invention that uses the variation of oscillation frequency over the tuning range to provide data that determines the setting for the operating frequency.

### DETAILED DESCRIPTION OF THE PREFERRED EMBODIMENT(S)

The preferred embodiment uses a single mode that is tuned between different operating conditions. This is predicated on the observation that tuning an individual resonance to a different frequency shifts the temperature at which an activity dip has the most deleterious effects. There are two attractions to using different tunings of a single mode: first, that the variation of mode structure can be smaller than between different modes; and second, that one can utilise the systematic behaviour of the tuning-temperature dependence of activity dips to minimise the complexity of the solution—the issue this latter overcomes is that the activity dips of different modes are essentially uncorrelated. For AT quartz crystals, the most troublesome modes have temperature coefficients in the region of 20-to-30 ppm/° C. FIG. 2 shows a case where 400-ppm tuning of the wanted resonance frequency shifts the temperature of the activity dip by 20° C.

The invention also takes advantage of the fact that, in navigation systems and recovery beacons, the actual output frequency of the oscillator is not usually critical (provided that it is known with adequate accuracy) and extreme stability is only required for limited periods of time, or “critical periods”, enabling the oscillator to be set shortly before the start of each critical period.

It is therefore possible at the start of each critical period to tune the oscillator to a frequency that is relatively remote from the resonance frequency of critical unwanted modes. This allows the use of a resonator that has an unwanted mode whose resonance frequency passes through the resonance frequency range of the wanted mode within the required operational range of the oscillator.

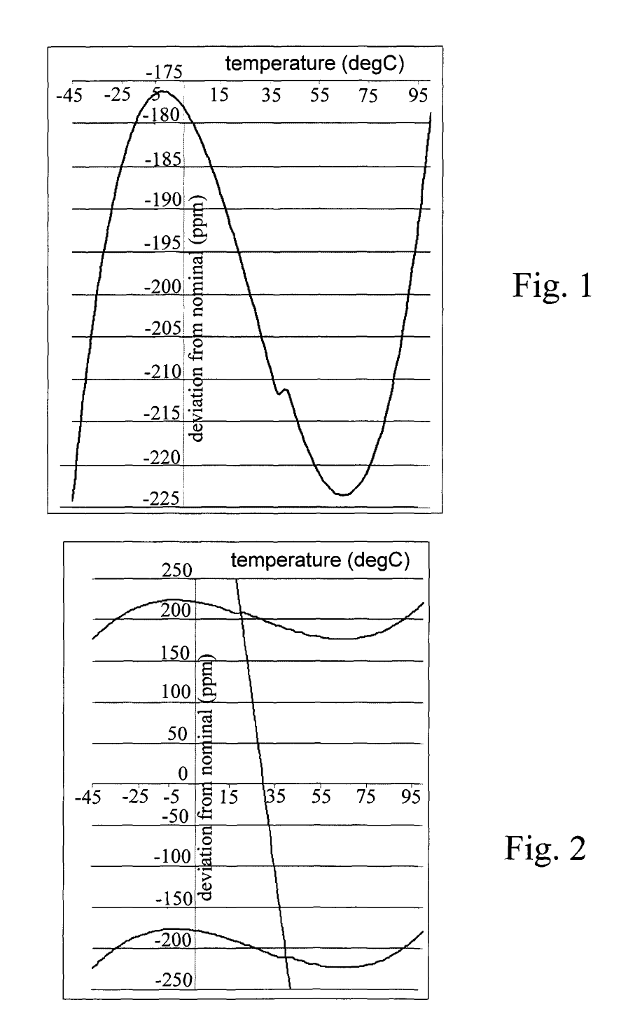

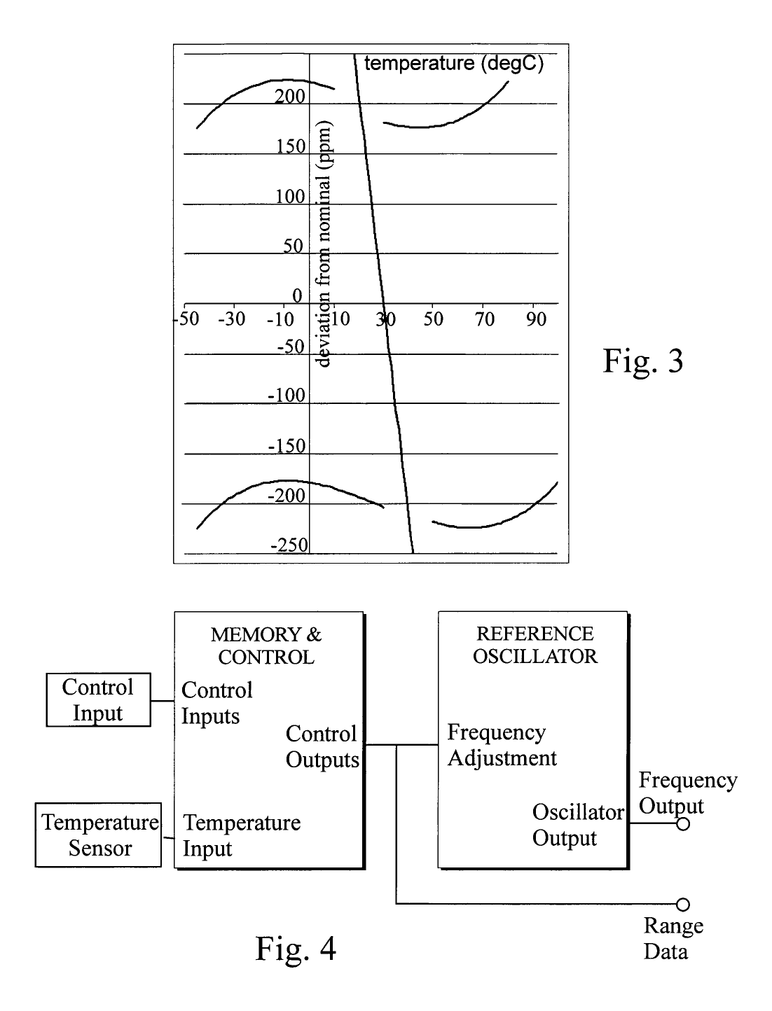

FIG. 3 illustrates potential start-frequencies versus temperature that will reduce the effect of the activity dip of FIGS. 1 and 2. As compared with allowing operation at the centre of the activity dip, this provides a factor of 14 reduction in deleterious effects—i.e. both in contribution to the temperature gradient and in sensitivity to frequency steps in the unwanted resonance.

It will be observed that either of the two settings illustrated can be used over much of the temperature range. This freedom may be used to avoid other activity dips if these are present; otherwise, the choice will be largely arbitrary or determined by other factors. Clearly, it may be that simply providing a pair of offsets may be inadequate in the presence of multiple activity dips having different characteristics; in this case, a multiplicity of offset settings may prove convenient.

Such a tuning arrangement requires that the appropriate setting at the start time be known. This may in principle be achieved by calibrating the activity of the oscillator across the tuning range immediately prior to setting. However, depending on the sensitivity to activity variations that is required, this could appreciably extend the start-up time. Alternatively, if an oscillator with adequate stability is available, the frequency effect could be detected somewhat more rapidly. More commonly, however, the oscillator will need to be pre-calibrated for other reasons, so the calibration data can be stored long term in memory.

FIG. 4 shows a system diagram for a system that relies on pre-calibration and operates as follows:

Shortly prior to a critical period during which a stable frequency is required, a signal is applied to a control input that starts a set-up procedure. This procedure uses temperature data to predict approximately the temperature range that will be experienced during operation. This, together with data stored in memory, is used to tune the oscillator to a frequency adjustment setting that, throughout the expected temperature range, is remote from the centre frequency of known potentially troublesome activity dips. For the avoidance of doubt, the temperature data used may be a single temperature measurement, or it may be a history that establishes likely trends during the operational period.

The oscillator may be permanently maintained at a frequency that avoids activity dips by keeping track of an operating parameter such as temperature. However, this would require the frequency of the oscillator to be changed from time to time, be it abruptly or continuously. In such an embodiment, even though the selection of the oscillator frequency is performed prior to, rather than after, the initiation of a start-up procedure, it is essential to ensure that no adjustment be made to the frequency during the critical period. Such an embodiment of the invention offers the advantage that less time is needed between the initiation of a set-up procedure and the critical period during which measurement takes place.

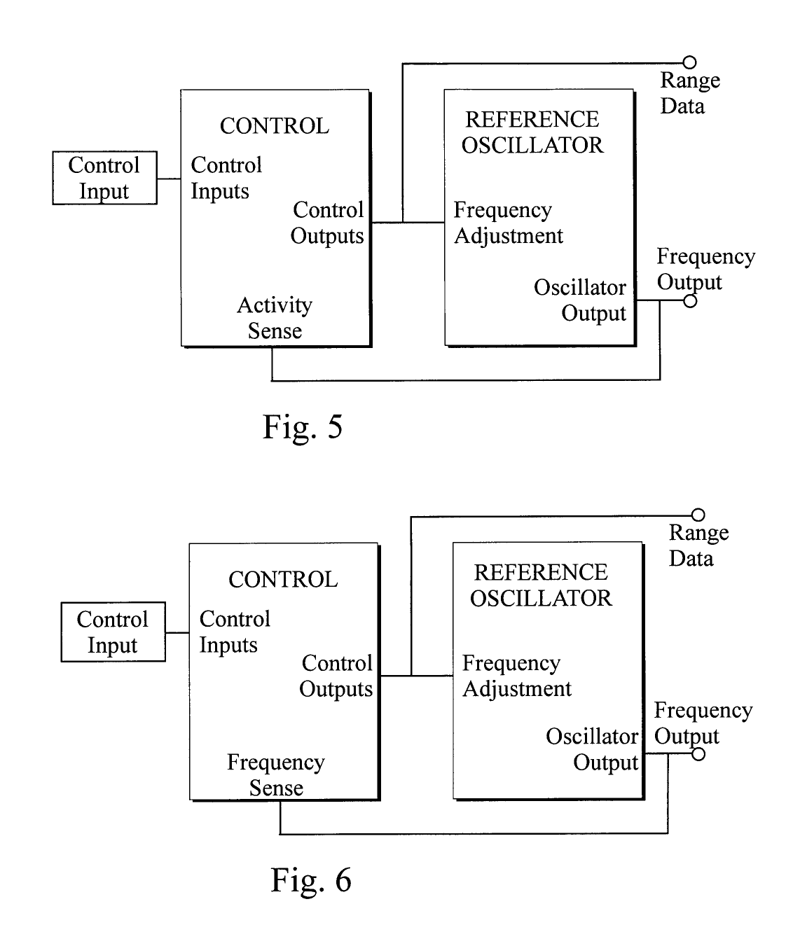

FIG. 5 and FIG. 6 show systems where the optimum operating frequency is determined by the control circuit by analysing the performance of the oscillator at different operating frequencies. In FIG. 5, the control circuit senses an activity dip while the embodiment of FIG. 6 analyses the anomalies in the output frequency of the reference oscillator.

As for the arrangement illustrated in FIG. 4, a signal applied to the control input starts a set-up procedure. During set-up, some part of the frequency adjustment range of the oscillator is scanned, and measurements of the oscillator output determine frequency adjustment settings at which the oscillator is relatively free from activity dips.

Once the oscillator circuit is set to a suitable operational condition, the effects of intrinsic frequency-temperature drift may be minimised in a number of ways.

For the most critical applications it may prove most beneficial to minimise crystal temperature variations during the measurement period; this could be by preliminary heating the system to a temperature slightly above ambient; however, given that the temperature range will usually be much smaller than the worst case, it may be more efficient to maintain the temperature at its start value using a heater-cooler based on (for example) the Peltier effect.

Alternatively, the reactance of the oscillator circuit can be continuously tuned to maintain a stable frequency, in a manner similar to conventional temperature compensated crystal oscillator. Potentially, the limited temperature range for each period can be used to simplify the compensation circuitry and/or improve performance—albeit this will naturally require additional memory or digital pre-computation.

An additional possibility is to compensate the bulk of the frequency-temperature variation using capacitors with known variation with changing temperature. Variation in capacitor value may be accomplished by switching of capacitor value or presence. A switched capacitor may be a temperature-compensating capacitor.

The use of temperature-compensating capacitors offers in principle two possible benefits: first, this part of the compensation is not susceptible to the effects of the noise that usually accompanies semiconductor temperature sensing; second, the capacitor may be placed where its temperature best tracks that of the crystal. The tracking advantage potentially applies also to the temperature-stabilised arrangement described above.

An additional method, which may of course be combined with any of the above techniques, would be to provide expected-frequency data to a suitable processor in the navigation system. The data could then either be used to synthesize a stable frequency, or to support a post-mixing calculation-based correction system.

1. A resonator-controlled oscillator arrangement, comprising a resonator-controlled oscillator of which the operating frequency is adjustable and a control circuit for setting the operating frequency of the oscillator, wherein the control circuit is operative to set the operating frequency in dependence upon prevailing ambient conditions, and wherein the control circuit has a control input for initiating a set-up procedure during which the operating condition of the oscillator is set to, or maintained at, a value remote from any resonance frequency of a coupled mode that would cause an activity dip.

2. A resonator-controlled oscillator arrangement as claimed in claim 1, wherein the control circuit is further operative to produce an output signal indicative of the value to which the operating frequency of the oscillator has been set.

3. A resonator-controlled oscillator arrangement as claimed in claim 1, wherein activity dips are avoided by tuning a single resonant mode of the resonator to one of at least two different operating conditions.

4. A resonator-controlled oscillator arrangement as claimed in claim 3, wherein the tuning is accomplished by varying the value of a capacitor or capacitors.

5. A resonator-controlled oscillator arrangement as claimed in claim 4, wherein variation in capacitor value is accomplished by switching of capacitor value or presence.

6. A resonator-controlled oscillator arrangement as claimed in claim 5, wherein a switched capacitor is a temperature-compensating capacitor.

7. A resonator-controlled oscillator arrangement as claimed in claim 1, wherein the control circuit comprises an environmental parameter measurement input and the set-up procedure uses the environmental data and a look-up table to determine the operating frequency of the oscillator.

8. A resonator controlled oscillator according to claim 7, wherein the measured environmental parameter is temperature.

9. A resonator-controlled oscillator arrangement as claimed in claim 1, wherein an oscillation signal from the resonator controlled oscillator is applied to an input to the control circuit, and the set-up procedure utilises parameters of the oscillation signal at a plurality of operating frequencies to determine the occurrence of an activity dip.

10. A resonator-controlled oscillator arrangement as claimed in claim 9, wherein the occurrence of an activity dip is determined by the control circuit from the amplitude of the oscillation signal or the setting of a control signal used to stabilise such amplitude.

11. A resonator-controlled oscillator arrangement as claimed in claim 1, wherein the temperature of the oscillator is stabilised during a measurement period.

12. A resonator-controlled oscillator arrangement as claimed in claim 1, wherein the control circuit is operative to tune the oscillator in dependence upon a signal indicative of environmental conditions, such as to maintain the operating frequency substantially constant during a measurement period.

13. A method of operating a resonator-controlled oscillator arrangement that comprises a resonator-controlled oscillator of which the operating frequency is adjustable and a control circuit for setting the operating frequency of the oscillator, the method comprising:
applying an initiation signal to an input of the control circuit prior to the commencement of a critical period during which the output frequency of the oscillator is to be maintained stable,
selecting by the control circuit an operating frequency value that is remote from any resonance frequency of a coupled mode that would cause an activity dip at the prevailing ambient conditions, and
setting or maintaining the operating frequency of the oscillator at the selected value for the duration of the critical period.

14. A method as claimed in claim 13, wherein the control circuit selects the operating frequency based on measurement of an operating parameter and data stored in a table to indicate the optimum frequency value at the prevailing value of the measured operating parameter.

15. A method as claimed in claim 13, wherein the control circuit selects the operating frequency by analysing the performance of the oscillator at different operating frequencies.
